(19) United States
(12) Patent Application Publication
(10) Pub. No.: US 2005/0206427 A1
(43) Pub. Date: Sep. 22, 2005

(54) Semiconductor integrated circuit device

(75) Inventors: Yuichi Yuasa, Sapporo (JP); Shigemitsu Tahara, Chitose (JP); Daisuke Katagiri, Chitose (JP)

Correspondence Address: MILES & STOCKBRIDGE PC, 1751 PINNACLE DRIVE, SUITE 500, MCLEAN, VA, 22102-3833, US

(73) Assignees: Renesas Technology Corp.; Renesas Northern Japan Semiconductor, Inc.

(21) Appl. No.: 10/912,069

(22) Filed: Aug. 6, 2004

(30) Foreign Application Priority Data
Aug. 7, 2003 (JP) JP2003-289317

(51) Int. Cl. G11C 5/00

(52) U.S. Cl. 327/262

(57) ABSTRACT

There is provided a semiconductor integrated circuit device that enables an EMS-voltage withstanding margin to be significantly enhanced without increasing a chip-layout area etc. An input buffer section, a CR filter composed of a resistor and an electrostatic capacitor device, a Schmitt circuit, and a noise cancellation circuit are connected to a system control terminal of the semiconductor integrated circuit device. When a signal containing noise is inputted to the system control terminal, a peak of the noise is reduced by an input buffer composed of the Schmitt circuit provided in the input buffer section. Thereafter, the peak of the noise is further reduced by the CR filter. Subsequently, the signal passes through the Schmitt circuit, thereby being significantly removed.

### CROSS-REFERENCE TO RELATED APPLICATION

The present application claims priority from Japanese patent application No. JP 2003-289317 filed on Aug.7, 2003, the content of which is hereby incorporated by reference into this application.

### BACKGROUND OF THE INVENTION

The present invention relates to a manufacturing technique for a semiconductor device and more specifically to a technique effectively applied to manufacture of an insulated gate field effect transistor that is formed on a thin semiconductor film over an insulation film.

Recently, with advance of a technology for making an electronic system operate at lower voltage and high speed, etc., there have been increased demands for miniaturization and low-voltage operations, etc. of a single-chip microcomputer etc. used with the above electronic system. Also, with advance of a technology for making a semiconductor integrated circuit device such as a single-chip microcomputer operate at low voltage, distinction between EMS (Electro Magnetic Susceptibility) noise and normal signals becomes difficult and therefore improvement at noise levels is required.

Some semiconductor integrated circuit devices are provided with system control terminals to which control signals each having a long cycle, such as reset signals and standby signals, are inputted, in addition to input/output (I/O) terminals. The system control terminal is provided with a noise cancellation circuit, which identifies the normal signals and the noise, to prevent erroneous operations of the semiconductor integrated circuit device.

The noise cancellation circuit is configured by, for example, a delay circuit in which a plurality of inverters are connected in series, and the noise cancellation circuit is a circuit that outputs the inputted signal as a normal signal when the inputted signal is longer than a signal delayed by a predetermined period of time through the delay circuit.

### SUMMARY OF THE INVENTION

However, the inventors have discovered that such a noise cancellation technique employed in the semiconductor integrated circuit device have the following problems.

That is, there is the fear that when the noise having a cycle longer than the delay time by the delay circuit is inputted to the system control terminal, it is outputted as a normal signal and thereby the erroneous operations of the semiconductor integrated circuit device are caused.

Also, there is the problem that when the high-voltage noise is inputted into the system control terminal, the noise gives an influence between power supply voltages and thereby the erroneous operations of the semiconductor integrated circuit device, and the destruction of the semiconductor device, etc. are caused.

By way of measures of the high-voltage noise, for example, a noise removal component such as a bypass condenser is provided on a printed board, on which a semiconductor integrated circuit device is mounted, to remove the noise. However, it has been difficult to ensure a space etc. for mounting an external component due to the miniaturization etc. of the electronic system.

In addition, as the semiconductor integrated circuit device has higher functions, an analysis of EMC (Electro Magnetic Compatibility) becomes difficult and the noise measures taken by a side of the printed board become difficult and increase of the number of steps and the lengthening of design, etc. have not been negligible.

An object of the present invention is to provide a semiconductor integrated circuit device that enables an EMS-voltage withstanding margin to be significantly enhanced without increasing a chip-layout area etc.

The above and other objects and novel features of the present invention will become apparent from the description of this specification and the accompanying drawings.

Outlines of representative ones of inventions disclosed in the present application will be briefly described as follows.

A semiconductor integrated circuit device according to the present invention has a system control terminal, and comprises a noise removal filter provided to a subsequent stage of an input buffer coupled to said system control terminal.

Also, the semiconductor integrated circuit device according to the present invention further comprises a Schmitt circuit provided to a subsequent stage of said noise removal filter.

Moreover, in the semiconductor integrated circuit device according to the present invention, said Schmitt circuit is disposed near a power supply voltage terminal and a reference potential terminal.

Additionally, the semiconductor integrated circuit device according to the present invention further comprises a noise cancellation circuit in which a plurality of delay devices are in series connected to a subsequent stage of said Schmitt circuit.

Effects of representative ones of inventions disclosed in the present application will be briefly described as follows. (1) By using the Schmitt circuit and the noise removal means, exogenous noise having been inputted to the system control terminal can be significantly reduced without increasing layout size of a semiconductor chip. (2) Since the Schmitt circuit is disposed near the power supply terminal, the noise propagating through a power supply line can be minimized. (3) Due to items (1) and (2), since the semiconductor integrated circuit device is used to constitute an electronic system, it is unnecessary to take measures of the noise on a side of a mounting board of the electronic system. Therefore, it is possible to reduce the design and development period, the number of external components, and the area of the mounting board, etc.

### BRIEF DESCRIPTION OF THE DRAWINGS

FIG. 1 is a layout diagram showing a chip of a semiconductor integrated circuit device according to an embodiment of the present invention.

FIG. 2 is a circuit diagram showing a noise removal circuit connected to a system control terminal provided in the semiconductor integrated circuit device shown in FIG. 1.

FIG. 3 is a circuit diagram showing a configuration of a noise cancellation circuit provided in the noise removal circuit shown in FIG. 2.

FIG. 4 is a view showing circuit layout of the noise removal circuit shown in FIG. 2.

FIG. 5 is a layout diagram showing a semiconductor chip for the noise removal circuit shown in FIG. 2.

FIG. 6 is an explanatory view of a noise reduction by the noise removal circuit shown in FIG. 2.

FIG. 7 is an explanatory view showing a noise reduction by the noise removal circuit subsequently to FIG. 6.

FIG. 8 is an explanatory view showing a noise reduction by the noise removal circuit subsequently to FIG. 7.

FIG. 9 is an explanatory view showing a noise reduction by the noise removal circuit subsequently to FIG. 8.

### DESCRIPTION OF THE PREFERRED EMBODIMENTS

Hereinafter, an embodiment of the present invention will be detailed based on the drawings.

(Embodiment)

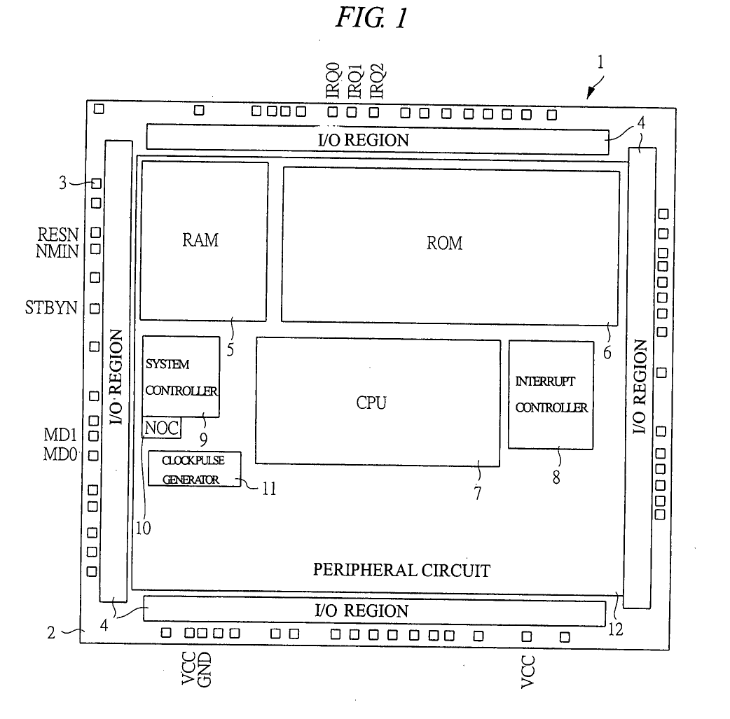

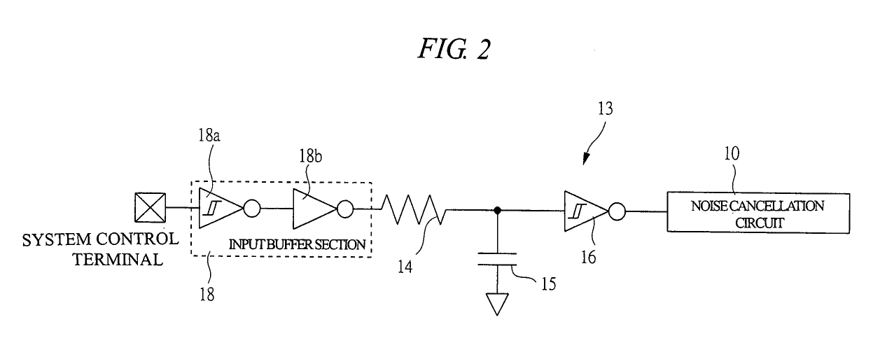

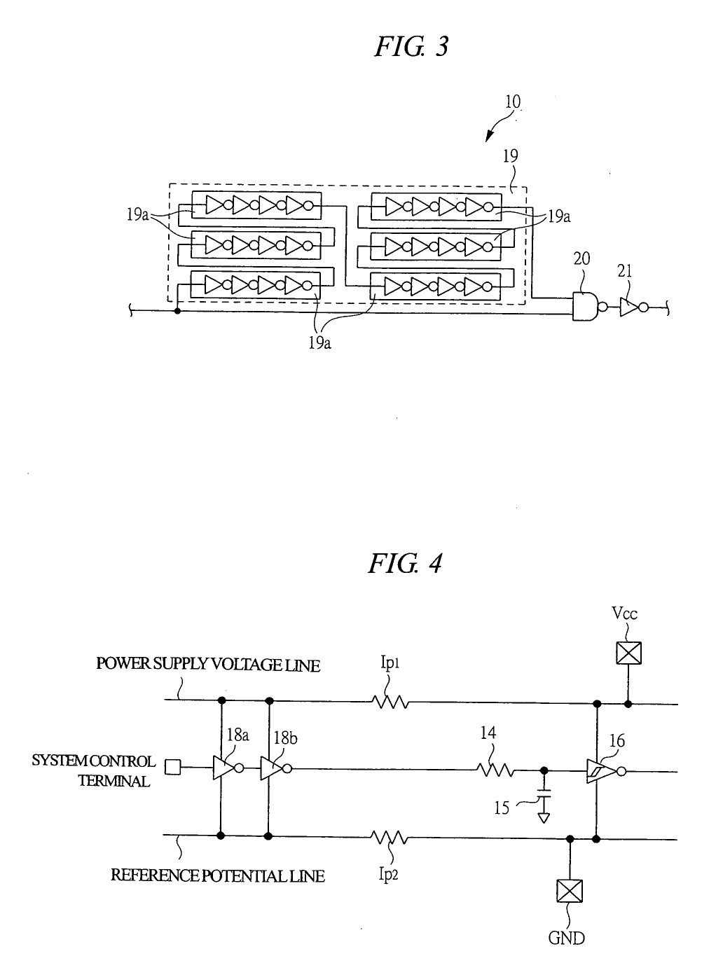

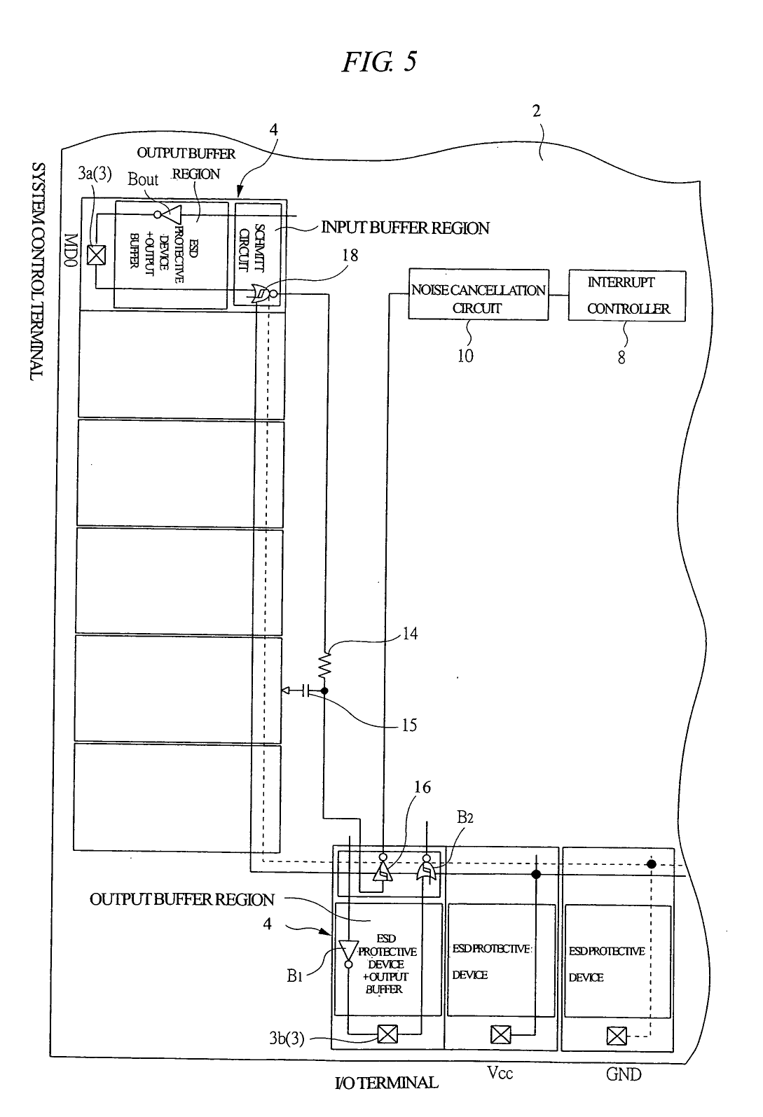

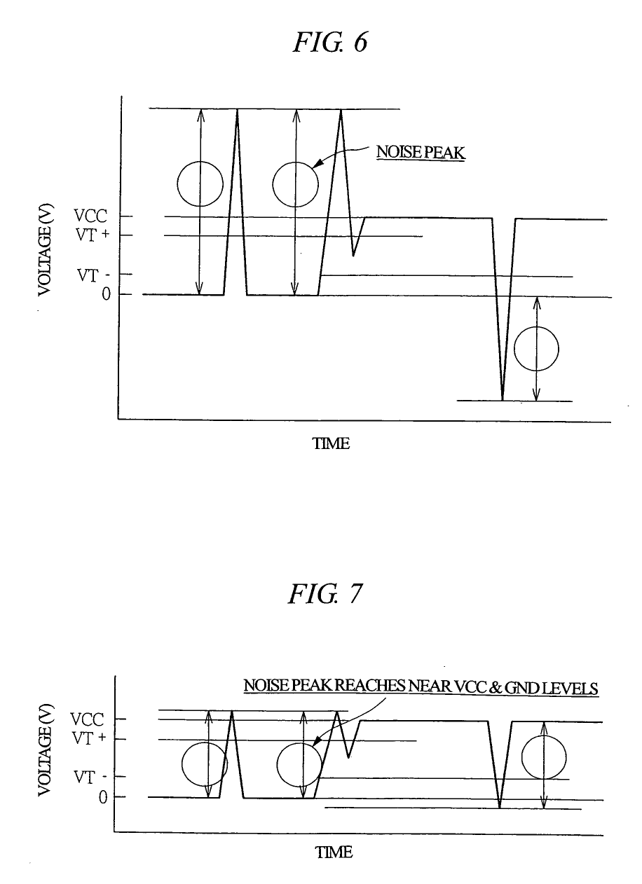

FIG. 1 is a layout diagram showing a chip of a semiconductor integrated circuit device according to an embodiment of the present invention; FIG. 2 is a circuit diagram showing a noise removal circuit connected to a system control terminal provided in the semiconductor integrated circuit device shown in FIG. 1; FIG. 3 is a circuit diagram showing a configuration of a noise cancellation circuit provided in the noise removal circuit shown in FIG. 2; FIG. 4 is an explanatory view showing circuit layout of the noise removal circuit shown in FIG. 2; FIG. 5 is a layout diagram showing a semiconductor chip for the noise removal circuit shown in FIG. 2; and FIGS. 6 to 9 are explanatory views of a noise reduction by the noise removal circuit shown in FIG. 2.

In the present embodiment, a semiconductor integrated circuit device 1 is, for example, a single-chip microcomputer for use with a motor vehicle, a home-use electrical appliance, or the like. As shown in FIG. 1, in the semiconductor integrated circuit device 1, a plurality of chip electrodes 3 are individually provided in four peripheral portions of a semiconductor chip 2.

The chip electrodes 3 are connected to external terminals through, for example, bonding wires. As the external terminal, an I/O terminal, a clock terminal, a power supply terminal, and a system control terminal, etc. are provided.

The I/O terminal is a terminal for inputting and outputting various signals, and the clock terminal is a terminal used for connection to a quartz oscillator or the like. The power supply terminal comprises, for example, a power supply voltage terminal VCC to which power supply voltage is coupled, and a ground terminal (reference potential terminal) GND to which reference potential is applied, and the like.

The system control terminal comprises a plurality of terminals such as interrupt request terminals IRQ0 to IRQ2, a nonmaskable interrupt request terminal NMIN, operation mode control terminals MD1 and MD0, a reset terminal RESN, and a standby terminal STBYN. A noise removal circuit 13 (in FIG. 12) is connected to the system control terminal.

The interrupt request terminals IRQ0 to IRQ2 are maskable interrupt request terminals, and the nonmaskable interrupt request terminal NMIN is a terminal that cannot be masked. The operation mode control terminals MD1 and MD0 are terminals for setting operation modes of the semiconductor integrated circuit device 1.

The reset terminal RESN is a terminal for setting all functionalities to a reset state. The standby terminal STBYN is a terminal for setting a standby mode in which all the functionalities of the semiconductor integrated circuit device 1 are stopped.

The layout of the power supply terminal and the system control terminal will be described hereinafter.

The fourth one of the chip electrodes 3 downwardly laid out from the upper left of the semiconductor chip 2 is the reset terminal RESN. The nonmaskable interrupt request terminal NMIN is disposed below the reset terminal RESN.

The second one of the chip electrodes 3 disposed below the nonmaskable interrupt request terminal NMIN is the standby terminal STBYN. The operation mode control terminal MD1 is located at the fourth position below the standby terminal STBYN, and the operation mode control terminal MD0 is positioned below the operation mode control terminal MD1.

In the lower chip electrodes 3 of the semiconductor chip 2, the power supply voltages VCC are disposed respectively in the second positions from the left and from the right, and the ground terminal GND is provided on the right of the second left power supply voltage VCC.

Further, in the upper chip electrodes 3 of the semiconductor chip 2, the ninth electrode from the right is the interrupt request terminal IRQ2, and the interrupt request terminal IRQ1 is positioned on the left of the interrupt request terminal IRQ2. The interrupt request terminal IRQO is provided on the left of the interrupt request terminal IRQ1.

I/O regions 4 composed of input and output circuits for data or the like are respectively provided inside an array of the chip electrodes 3. A RAM 5 (Random Access Memory) is provided at a lower left portion of the upper I/O region 4, and a ROM 6 (Read Only Memory) is provided on the right of the RAM 5. A CPU 7 (Central Processing Unit) is provided in a central portion of the semiconductor chip 2, and an interrupt controller 8 is provided on the right of the CPU 7.

The ROM 6 is composed of a nonvolatile memory, and a control program and the like are stored therein. The RAM 5 is composed of a nonvolatile memory such as an SRAM (Static RAM), in which, for example, the control programs stored in the ROM 6, operation results of the CPU 7, and externally inputted data are temporarily stored, thereby being used as a work area of the CPU 7.

The CPU 7 executes predetermined processes in accordance with the control programs stored in the ROM 6, and manages total control of the semiconductor integrated circuit device 1. The interrupt controller 8 determines priorities of interrupt factors from the interrupt signals inputted through the system control terminal, and controls interrupt requests issued to the CPU 7.

A system controller 9 is provided on the left of the CPU 7, and a noise cancellation circuit 10 is provided below the system controller 9. A clock pulse generator 11 is provided below the noise cancellation circuit 10.

The system controller 9 manages the control of system operation in accordance with a control signal, which are inputted through the system control terminal, such as a reset signal, standby signal and a mode signal. The noise cancellation circuit 10 cancels noise in the control signal having been inputted through the system control terminal. The clock pulse generator 11 generates a clock signal of a specific frequency to supply a system clock as an operation clock.

A peripheral circuit 12 is provided below the CPU 7. The peripheral circuitry 12 is composed of, for example, a DMA (Direct Memory Access) controller, a timer, a serial interface, and a parallel interface, etc.

The DMA controller is a control circuit for performing a DMA process. The timer counts up a timer clock etc., and outputs timer counter signals. The serial interface is an interface for transmitting and receiving serial signals, and the parallel interface is an interface for transmitting and receiving parallel signals.

FIG. 2 is an explanatory view showing the configuration of the noise removal circuit 13 connected to each of the system control terminals.

The noise removal circuit 13 is composed of a resistor 14 (noise removal filter), an electrostatic capacitor device 15 (noise removal filter), a Schmitt circuit 16, and the noise cancellation circuit 10 shown in FIG. 1. One connection portion of the resistor 14 is coupled to the system control terminal via an input buffer section 18.

The input buffer section 18 is provided in the I/O region 4, and is composed of an input buffer 18a and an inverter 18b. The input buffer 18a is composed of a Schmitt circuit, and determines a High/Low level of the signals inputted in accordance with a Schmitt level.

One connection portion of the electrostatic capacitor device 15 and an input portion of the Schmitt circuit 16 are coupled to the other connection portion of the resistor 14. The reference potential (GND) is coupled to the other connection portion of the electrostatic capacitor device 15. The electrostatic capacitor device 15 and the resistor 14 constitute a CR filter.

The CR filter is used to remove noise present in the high voltage inputted through the system control terminal. Since the CR filter is thus coupled to a subsequent stage of the input buffer 18a composed of the Schmitt circuit, it is possible to take measures of CR value within a degree of level, which does not influence the chip size.

In the Schmitt circuit 16, the noise that cannot be removed by the CR filter is determined in the Schmitt level, and then the noise is removed. An input portion of the noise cancellation circuit 10 is coupled to an output portion of the Schmitt circuit 16.

The interrupt controller 8 (or the system controller 9) is coupled to the output portion of the noise cancellation circuit 10. As shown in FIG. 3, the noise cancellation circuit 10 is composed of a delay circuit 19, a NAND circuit 20, and an inverter 21.

An output portion of the Schmitt circuit 16 is connected to each of an input portion of the delay circuit 19 and the other input portion of the NAND circuit 20, and therefore the control signals outputted from the Schmitt circuit 16 are inputted thereto.

One input portion of the NAND circuit 20 is coupled to an output portion of the delay circuit 19, and an input portion of the inverter 21 is coupled to an output portion of the NAND circuit 20. An output portion of the inverter 21 is used as an output portion of the noise cancellation circuit 10.

The delay circuit 19 is composed of delay sections 19a, such as CMOS inverters (delay devices), which are less in production tolerance, and further composed of a plurality of delay sections 19a coupled in series. The delay sections 19a are arranged so that the number of the delay sections to be connected is reduced or increased depending on the control signal to be inputted to the system control terminal, thereby being adjusted respectively so as to have an optimal delay time for an input timing in accordance with the above-mentioned control signal.

FIG. 4 is an explanatory view showing circuit layout in the noise removal circuit 13.

Some of the system control terminals are disposed at long distance from the power supply terminal. However, as shown in the drawing, the Schmitt circuit 16 in the noise removal circuit 13 is disposed as close as possible to the power supply voltage terminal VCC and the ground terminal GND, which are the above-mentioned power supply terminals.

Due to influences of a wiring impedance Ip1 of a power supply voltage line and a wiring impedance Ip2 of a reference potential line, there is a possibility that exogenous noise to be inputted from the system control terminal will propagate through the power supply voltage line and the reference potential line. However, the Schmitt circuit 16 can be stably operated without being influenced by the noise, by disposing the Schmitt circuit 16 to be as close as possible to the power supply voltage VCC and the ground terminal GND, as described above.

FIG. 5 is a chip layout diagram showing the noise removal circuit 13 laid out on the semiconductor chip 2. Note that FIG. 5 shows a layout diagram of the noise removal circuit 13 in the mode control terminal MD0 as way of an example.

An output buffer Bout and an input buffer section 18 are respectively connected to a chip electrode 3a that is connected to the mode control terminal MD0. The I/O region 4 is composed of an output buffer region and an input buffer region, wherein the output buffer region is adjacent to the chip electrodes 3. The input buffer region is formed inside the chip of the output buffer region.

Each of the resistor 14 and the electrostatic capacitor device 15, which constitute the CR filter, is formed in an outer periphery of an internal circuit region composed of the CPU 7, and the ROM 6, etc., that is, in the vicinity of the I/O region 4. However, in the case where an internal-operation power supply voltage of the semiconductor integrated circuit device 1 is lower than the outer power supply voltage, the CR filter is laid out within the I/O region 4, whereby adverse effects by noise can be reduced.

The Schmitt circuit 16 to be connected to the CR filter is provided near the I/O region 4 of the chip electrodes 3 coupled to the power supply voltage terminal VCC and the ground terminal GND, as described with reference to FIG. 4.

In this case, since the chip electrodes 3, on which the power supply voltage VCC and the ground terminal GND are disposed, are the I/O terminals, the Schmitt circuit 16 is formed within the I/O region 4 of the chip electrode 3b closest to the power supply voltage terminal VCC and the ground terminal GND.

As described above, the I/O region 4 is composed of the output buffer region and the input buffer region. An output buffer B1 to be coupled to the chip electrode 3b is formed in the output buffer region, and an input buffer B2 to be coupled to the chip electrode 3b is formed in the input buffer region.

The Schmitt circuit 16 is formed together with the output buffer B2 in the input buffer region in the chip electrode 3b. Then, the Schmitt circuit 16 is connected to the noise cancellation circuit 10 formed in the internal circuit region, and the noise cancellation circuit 10 is connected to the interrupt controller 8.

In FIG. 5, the layout example of the noise removal circuit 13 to be coupled to the mode control terminal MD0 has been shown. However, similarly to a Schmitt circuit of a noise removal circuit 13 to be coupled to another system control terminal, the Schmitt circuit is disposed in the input buffer region in the chip electrode 3b, that is, at a portion that is as close as possible to the power supply voltage terminal VCC and the ground terminal GND, and so it is possible to prevent the noise from propagating through the power supply voltage line and the reference potential line and to stably operate the above-mentioned Schmitt circuit 16.

Next, the operation of the noise removal circuit 13 according to the present embodiment will be described.

FIGS. 6 to 9 are timing charts showing noise reduction effects on the CR filter composed of the resistor 14 and the electrostatic capacitor device 15 and on the Schmitt circuit 16. Note that, throughout FIGS. 6 to 9, the reference symbol “VT+” indicates a plus-side Schmitt level, and “VT−” indicates a minus-side Schmitt level.

First, when a signal having noise at any high-voltage level as shown in FIG. 6 is inputted to certain system control terminal, the noise is reduced by the input buffer 18a composed of the Schmitt circuit in the input buffer section 18 until a peak level of the nose reaches near a level of the power supply voltage/reference potential as shown in FIG. 7. At this moment, whether the above-mentioned signal is a normal signal to be supplied to the system terminal is not yet determined, and is determined by the noise cancellation circuit 10, as described below.

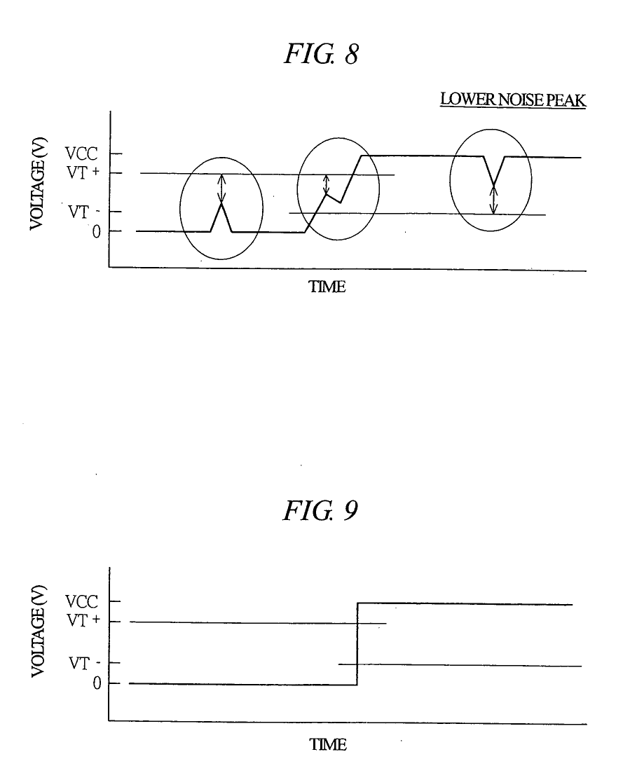

Thereafter, the noise is further reduced by the CR filter, whereby the peak of the noise is lowered. As shown in FIG. 8, all the noise peaks become equal to or higher than the Schmitt level VT− or equal to and lower than the Schmitt level VT+ by the CR filter.

Subsequently, the signal in which the noise has been reduced by the CR filter passes through the Schmitt circuit 16, whereby the noise is significantly reduced as shown in FIG. 9.

The High level signal, in which the noise has been reduced by the CR filter and the Schmitt circuit 16, is inputted to the noise cancellation circuit 10 and is determined whether it is a normal signal. The signal having been outputted from the Schmitt circuit 16 is inputted respectively to the other input portion of the NAND circuit 20 and the delay circuit 19.

The signal delayed by a specific time through the delay circuit 19 is inputted to the one input portion of the NAND circuit 20. When the High level delayed signal is outputted from the delay circuit 19, if the signal having been inputted to the other input portion of the NAND circuit 20 is the High level one, the Low level signal that is a normal signal is outputted from the above-mentioned NAND circuit 20.

The Low signal is inverted by the inverter 21 and is outputted, as a High level control signal, to the interrupt controller 8 (or the system controller 9) connected to the subsequent stage.

As described above, in the delay circuit 19, the delay time is adjusted, by increasing or reducing the number of the delay circuits 19 to be connected so that the noise cancellation time is optimized in accordance with the input timing set per control signal.

Also, the above description has been made by reference to the case where the control signal is the High level. However, by changing the circuit configuration that is to be connected to the output portion of the delay circuit 19, the measures can be taken even if the normal control signal is the Low level one.

Thus, according to the present embodiment, the exogenous noise to be inputted to the system control terminal can be significantly reduced by the Schmitt circuit 16 and the CR filter. Consequently, reliability of the semiconductor integrated circuit device 1 can be enhanced.

As described above, the invention made by the inventors has been specifically detailed based on the embodiment. However, needles to say, the present invention is not limited to the above-mentioned embodiment and can be variously modified and altered without departing from the gist thereof.

1. A semiconductor integrated circuit device having a system control terminal, the device comprising:
an input buffer constituted by a Schmitt circuit coupled to said system control terminal; and
a noise removal filter provided to a subsequent stage of the input buffer.

2. The semiconductor integrated circuit device according to claim 1,
wherein said noise removal filter is a CR filter composed of a resistor and an electrostatic capacitor device.

3. The semiconductor integrated circuit device according to claim 1, further comprising:
a Schmitt circuit provided to a subsequent stage of said noise removal filter.

4. The semiconductor integrated circuit device according to claim 3,
wherein said Schmitt circuit is disposed near a power supply voltage terminal and a reference potential terminal.

5. The semiconductor integrated circuit device according to claim 3, further comprising:
a noise cancellation circuit in which a plurality of delay devices are in series connected to a subsequent stage of said Schmitt circuit.

6. The semiconductor integrated circuit device according to claim 5,
wherein, the number of said delay devices to be connected per said system control terminal is adjusted so that said noise cancellation circuit may have an optimum time for an input timing per control signal inputted to said system control terminal.

7. The semiconductor integrated circuit device according to claim 3,
wherein said Schmitt circuit is disposed in an I/O region.

8. The semiconductor integrated circuit device according to claim 1,
wherein said noise removal filter is disposed in an I/O region.
